(19) United States
(12) Patent Application Publication
(10) Pub. No.: US 2026/0049686 A1
(43) Pub. Date: Feb. 19, 2026

(54) HOLDING MECHANISM AND BRACKET ASSEMBLY

(71) Applicant: Wistron Corp., New Taipei City (TW)

(72) Inventors: Chien Lin PAN, New Taipei City (TW); Jhe Ci LIN, New Taipei City (TW); Wen Sien SIAO, New Taipei City (TW); Kuan Hsun HUANG, New Taipei City (TW); Bao Jun CHEN, New Taipei City (TW)

(21) Appl. No.: 18/938,501

(22) Filed: Nov. 6, 2024

(30) Foreign Application Priority Data
Aug. 16, 2024 (TW) 113130830

(51) Int. Cl. F16M 13/02

(52) U.S. Cl. CPC F16M 13/02; F16M 2200/02

(57) ABSTRACT

A holding mechanism is provided, and includes a bottom plate, a clamp, a slider, and a knob. The clamp is movably disposed over the bottom plate. The slider is connected to the clamp and used to drive the clamp to move. The knob is rotatably disposed over the bottom plate, and abuts the slider. The slider is pushed to move the clamp towards the base by the knob. Accordingly, users may easily install the holding mechanism to the base by operating the knob of the holding mechanism. Therefore, installing the holding mechanism and the electric component held on it is made less difficult.

### CROSS REFERENCE TO RELATED APPLICATIONS

This application claims priority of Taiwan Patent Application No. 113130830, filed on Aug. 16, 2024, the entirety of which is incorporated by reference herein.

### BACKGROUND

### Technical Field

The disclosure is related to a holding mechanism and a bracket assembly, and in particular it is related to a holding mechanism and a bracket assembly that include a knob to push the clamps for installation.

### Description of the Related Art

With the advancements being made in science and technology, there are more and more applications for electronic equipment. In particular, electronic devices with communication functions have gradually become an indispensable part of daily life. However, there is still room for improvement in existing electronic devices in terms of ease of installation or removal.

### BRIEF SUMMARY

The present disclosure provides a holding mechanism, which includes a bottom plate, a clamp, a slider, and a knob. The clamp is movably disposed over the bottom plate. The slider is connected to the clamp and used to drive the clamp to move. The knob is rotatably disposed over the bottom plate, and abuts the slider. The slider is pushed to move the clamp towards the base by the knob.

The present disclosure provides a bracket assembly for carrying an electronic component. The bracket assembly includes a base and a holding mechanism. The holding mechanism is movably connected to the base and used to carry the electronic component. The holding mechanism includes a bottom plate and a cover plate. The cover plate is disposed opposite the bottom plate. The clamp is movably disposed over the bottom plate. The slider is connected to the clamp and used to drive the clamp to move. The knob is rotatably disposed on the bottom plate and abutting against the slider. The base is slidably disposed between the bottom plate of the holding mechanism and the clamp, and the slider is pushed to move the clamp toward the base by the knob, so that the bottom plate and the clamp contact opposite surfaces of the base respectively.

The present disclosure provides a bracket assembly for abutting against a display device. The bracket assembly includes a base and a holding mechanism movably connected to the base and used to abut against the display device. The holding mechanism includes a bottom plate, a clamp movably disposed over the bottom plate, a slider connected to the clamp and used to drive the clamp to move, and a knob rotatably disposed over the bottom plate. The knob is abutted against the slider. The base is slidably disposed between the bottom plate and the clamp of the holding mechanism, and the slider is pushed to move the clamp toward the base through the knob, so that the bottom plate and the clamp contact opposite surfaces of the base respectively.

### BRIEF DESCRIPTION OF THE DRAWINGS

The disclosure may be more fully understood by reading the subsequent detailed description and examples with references made to the accompanying drawings, wherein:

FIG. 1A illustrates a perspective view of a communication system in accordance with some embodiments of the present disclosure.

FIG. 1B illustrates an exploded view of an electronic device in accordance with some embodiments of the present disclosure.

FIG. 2 illustrates a perspective view of a holding mechanism and a base in accordance with some embodiments of the present disclosure.

FIG. 3A illustrates a plan view of the holding mechanism in accordance with some embodiments of the present disclosure.

FIG. 3B illustrates an exploded view of the holding mechanism in accordance with some embodiments of the present disclosure.

FIG. 3C illustrates a cross-sectional view of the holding mechanism along the line B-B shown in FIG. 3A in accordance with some embodiments of the present disclosure.

FIG. 3D illustrates a cross-sectional view of the holding mechanism along the line C-C shown in FIG. 3A in accordance with some embodiments of the present disclosure.

FIG. 4A illustrates a plan view of the holding mechanism in accordance with some embodiments of the present disclosure.

FIG. 4B illustrates a cross-sectional view of the holding mechanism along the line B-B shown in FIG. 4A in accordance with some embodiments of the present disclosure.

FIG. 4C illustrates a cross-sectional view of the holding mechanism along the line C-C shown in FIG. 4A in accordance with some embodiments of the present disclosure.

FIG. 5 illustrates a partial plan view of the holding mechanism in accordance with some embodiments of the present disclosure.

FIG. 6 illustrates a cross-sectional view of the holding mechanism along the line A-A shown in FIG. 5 in accordance with some embodiments of the present disclosure.

FIG. 7 illustrates a perspective view of the base and the supporting member in accordance with some embodiments of the present disclosure.

FIG. 8A illustrates an exploded view of the base and the supporting member in accordance with some embodiments of the present disclosure.

FIG. 8B illustrates an exploded view of the supporting member in accordance with some embodiments of the present disclosure.

FIG. 9A through 9C illustrate schematic views of various stages of the operation of the supporting member in accordance with some embodiments of the present disclosure.

FIG. 10 illustrates a perspective view of the base and the supporting member in accordance with some embodiments of the present disclosure.

FIG. 11 illustrates an exploded view of the base and the supporting member in accordance with some embodiments of the present disclosure.

FIG. 12 illustrates a partial cross-sectional view of the base and the supporting member in accordance with some embodiments of the present disclosure.

### DETAILED DESCRIPTION OF THE INVENTION

The holding mechanism and the bracket assembly of some embodiments of the present disclosure are described in the following description. However, it should be appreciated that the following detailed description of some embodiments of the disclosure provides various concepts of the present disclosure which may be performed in specific backgrounds that may vary widely. The specific embodiments disclosed are provided merely to clearly describe the usage of the present disclosure by some specific methods without limiting the scope of the present disclosure.

In addition, relative terms such as “down” or “bottom,” “up” or “top” may be used in the following embodiments in order to describe the relationship between one element and another element in the figures. It should be appreciated that if the device shown in the figures is flipped upside-down, the element located on the “down” side may become the element located on the “up” side.

It should be understood that although the terms “first,” “second,” etc. may be used herein to describe various elements, materials and/or portions, these elements, materials and/or portions are not limited by the above terms. These terms merely serve to distinguish different elements, materials and/or portions. Therefore, a first element, material and/or portion may be referred to as a second element, material and/or portion without departing from the teaching of some embodiments in the present disclosure. Unless defined otherwise, the first or second element, material and/or portion in the claims may be interpreted as any element, material and/or portion in the specification as long as it conforms to the description in the claims.

Unless defined otherwise, all terms (including technical and scientific terms) used herein have the same meaning as commonly understood by one of ordinary skill in the art to which the present disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined in the present disclosure. In addition, the terms “substantially,” “approximately” or “about” may also be recited in the present disclosure, and these terms are intended to encompass situations or ranges that is substantially or exact the same as the description herein. It should be noted that unless defined specifically, even if the above terms are not recited in the description, it should be read as the same meaning as those approximate terms are recited.

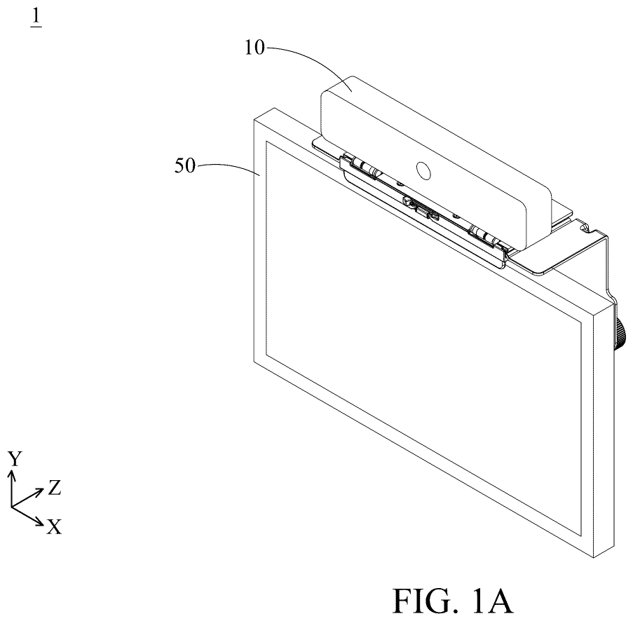

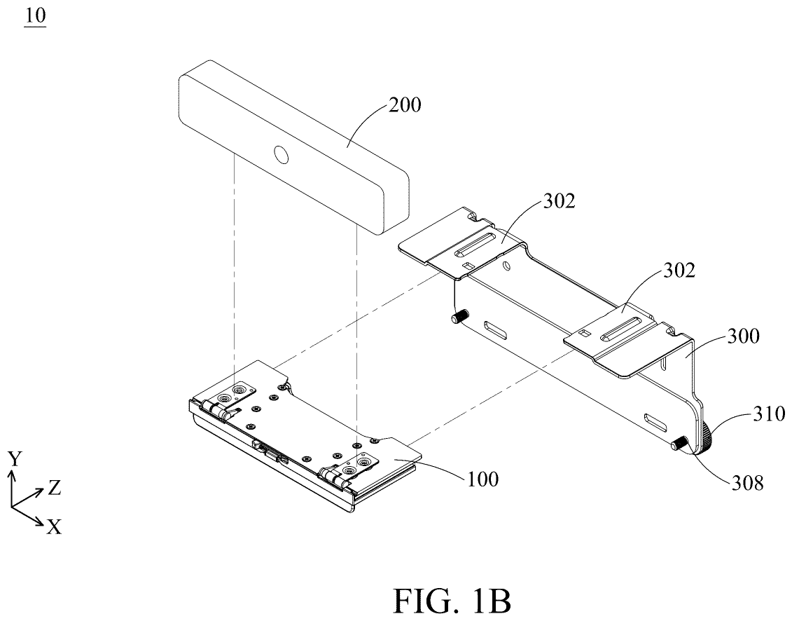

First, referring to FIG. 1A, which illustrates a perspective view of a communication system 1 in accordance with some embodiments of the present disclosure. It should be noted that the communication system 1 may include a display device 50 and an electronic device 10 installed over the display device 50. For example, the electronic device 10 may include a camera element. In this way, the user can view image information from the display device 50 and capture images using the electronic device 10 to achieve communication and interaction functions. However, the present disclosure is not limited thereto. The communication system 1 may include any electronic device that is installed on the display device 50 and cooperating with the display device 50 to implement various functions.

FIG. 1B illustrates an exploded view of the electronic device 10 in accordance with some embodiments of the present disclosure. As shown in FIG. 1B, the electronic device 10 includes a holding mechanism 100, an electronic component 200 and a base 300. The holding mechanism 100 is slidably coupled to the base 300 and is used to carry the electronic component 200. In some embodiments, the electronic component 200 can be installed on the display device 50 (as shown in FIG. 1A) via the holding mechanism 100 and the base 300. In particular, the base 300 may include holding portions 302 that are used to engage the holding mechanism 100. The electronic device 10 may include a plurality of locking members 310, and the locking members 310 may pass through the base 300 so as to affix the base 300 to the display device 50. For example, the locking members 310 may each pass through the through holes 308 of the base 300 and be disposed in the corresponding hole of the display device 50. However, the present disclosure is not limited thereto. In other embodiments, the locking members 310 may pass through the through holes 308 of the base 300 and be disposed at any suitable location (for example, on a wall).

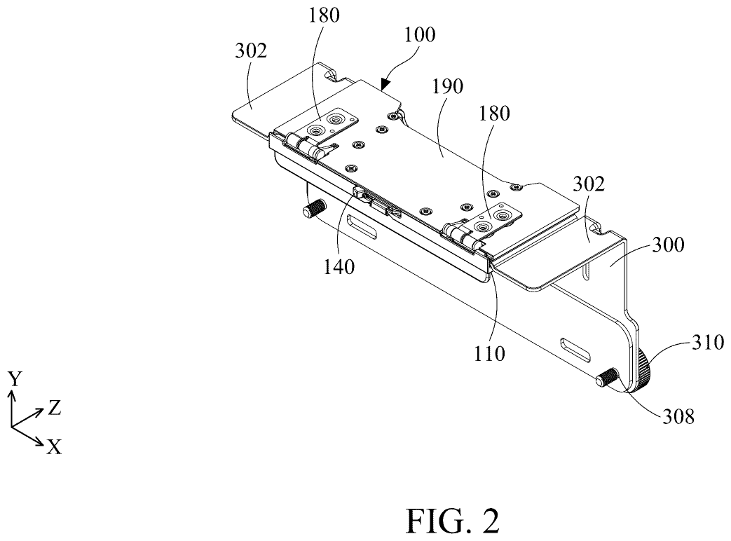

FIG. 2 illustrates a perspective view of the holding mechanism 100 and the base 300 in accordance with some embodiments of the present disclosure. As shown in FIG. 2, the holding mechanism 100 includes a bottom plate 110 and a cover plate 190. The cover plate 190 is disposed over the bottom plate 110, and the bottom plate 110 and the cover plate 190 collaboratively form an accommodation space. In some embodiments, the holding portions 302 of the base 300 are disposed in the accommodation space between the bottom plate 110 and the cover plate 190 to engage the base 300 with the holding mechanism 100. In addition, the holding mechanism 100 includes a knob 140, which is provided for users to operate the holding mechanism 100. Specifically, the users can operate the knob 140 to control the holding mechanism 100 to engage and lock the holding mechanism 100 with the base 300 (such as the holding portions 302), or to unlock the holding mechanism 100 and slide it relative to the base 300 (such as the holding portions 302) in the Z direction. In some embodiments, the knob 140 may partially protrude from the accommodation space to make it easier for the user to operate the holding mechanism 100. In addition, the holding mechanism 100 includes a joint member 180 that is used to engage the electronic component 200. The joint member 180 may be exposed from the cover plate 190.

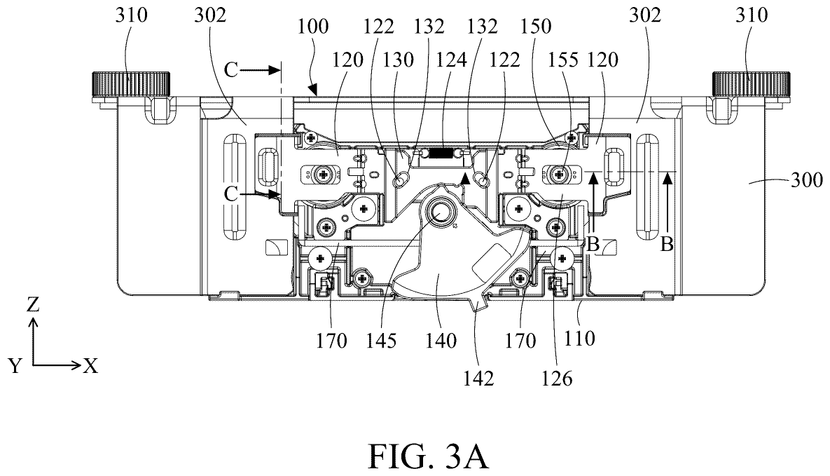

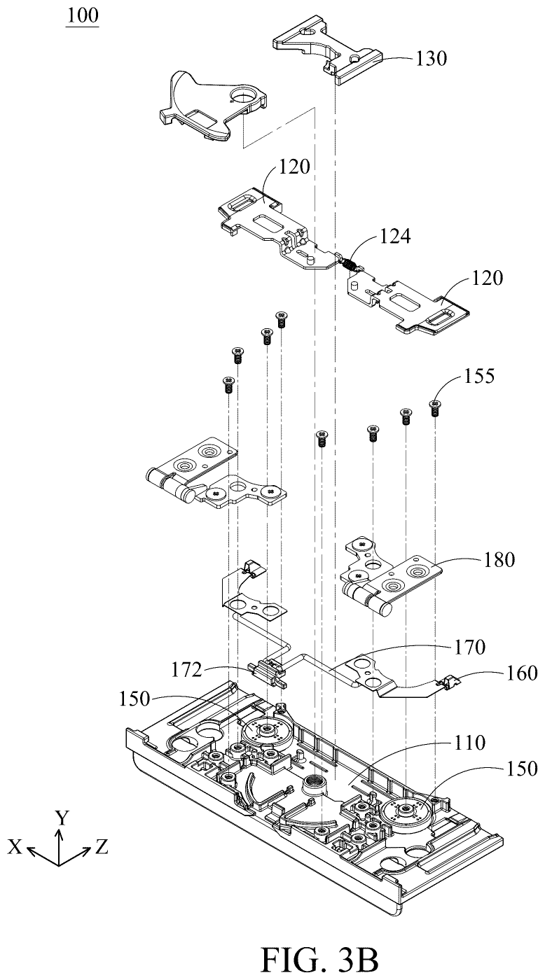

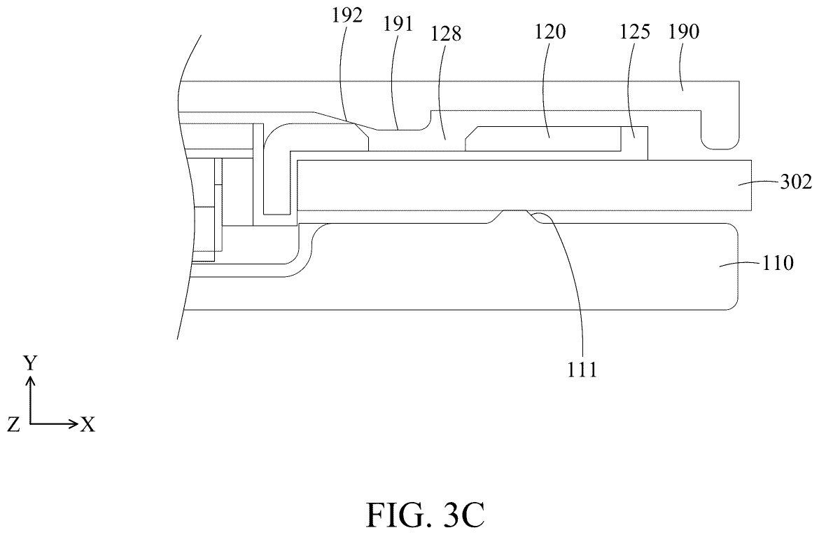

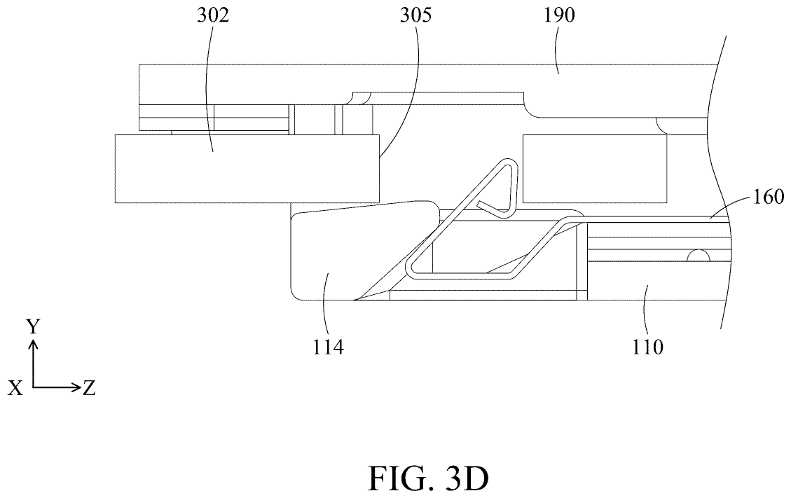

FIG. 3A illustrates a plan view of the holding mechanism 100 in accordance with some embodiments of the present disclosure. FIG. 3B illustrates an exploded view of the holding mechanism 100 in accordance with some embodiments of the present disclosure. As shown in FIGS. 3A and 3B, the holding mechanism 100 includes a plurality of clamps 120, which are movably disposed over the bottom plate 110. In some embodiments, the bottom plate 110 and the clamps 120 are used to contact the base 300 and clamp the base 300 (such as the holding portions 302) to fix the relative positions of the base 300 and the holding mechanism 100. In the present embodiment, the holding mechanism 100 includes two opposite clamps 120, which are connected to each other via a spring 124. In some embodiments, the spring 124 is used to exert a force on the clamps 120 so as to move the clamps 120 away from the base 300. As a result, when the users intend to install the holding mechanism 100 to the base 300 or remove the holding mechanism 100 from the base 300, the risk of mutual interference between the holding mechanism 100 and the base 300 can be reduced. In addition, the holding mechanism 100 includes a slider 130 that is connected to the clamps 120 and used to drive the clamps 120 to move. The knob 140 of the holding mechanism 100 can be pivotally connected to the bottom plate 110 via a cam 145, and the cam 145 abuts against the slider 130. The knob 140 includes an operating portion 142 that protrudes from the bottom plate 110. When the users operate the operating portion 142 of the knob 140, the knob 140 rotates around the cam 145 (which serves as the central axis) and pushes the slider 130 to move at the same time. As a result, the clamps 120 are driven to move. The slider 130 includes sliding grooves 132, each of which corresponds to a linkage portion 122 of each clamp 120. In particular, the linkage portions 122 of the clamps 120 can extend into the sliding grooves 132 to drive the clamps 120 to move along the extension direction (such as the Z direction) of the sliding grooves 132. In some embodiments, the extending directions of the sliding grooves 132 on the slider 130 may be different, that is, a non-zero included angle may be formed between the extending directions of different sliding grooves 132, but the present disclosure is not limited thereto.

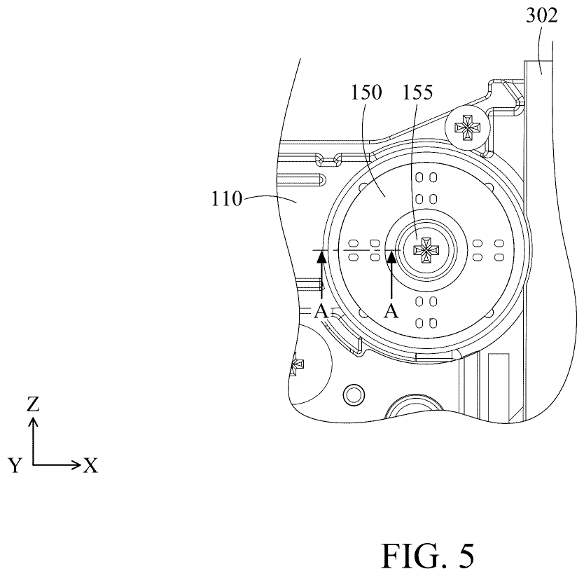

Referring to FIG. 5, in some embodiments, the holding mechanism 100 includes a clicker 150. The clicker 150 is rotatably disposed on the bottom plate 110 and is used to abut against the base 300 (such as the holding portion 302). The clicker 150 may be connected to the bottom plate 110 via the fixing member 155 and rotate around the fixing member 155, which serves as the central axis. Specifically, during the holding mechanism 100 being engaged with the base 300, the holding portion 302 can push the clicker 150 to rotate and make a sound, thereby reminding the user of the engagement distance between the base 300 and the holding mechanism 100. In some embodiments, the clamp 120 partially covers the clicker 150 to reduce the risk of the clicker 150 being damaged by external foreign objects. In addition, the clamp 120 includes an opening 126 to expose the fixing member 155. In this way, the convenience of adjusting or maintaining the fixing member 155 can be improved.

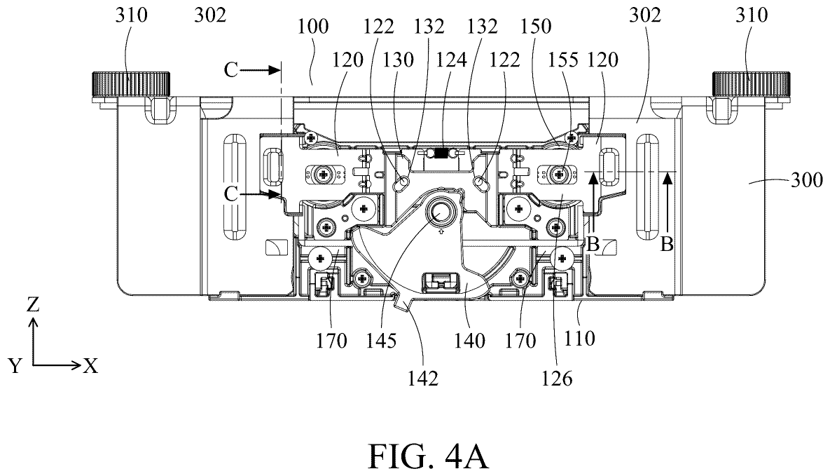

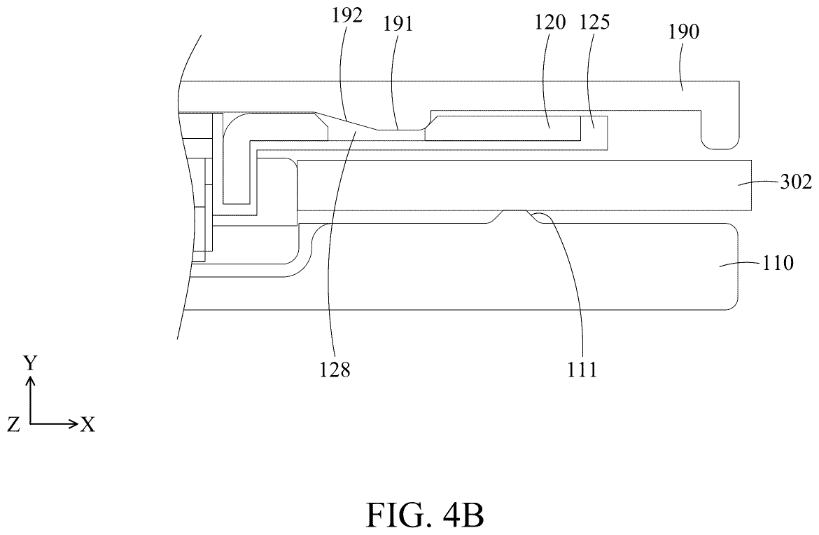

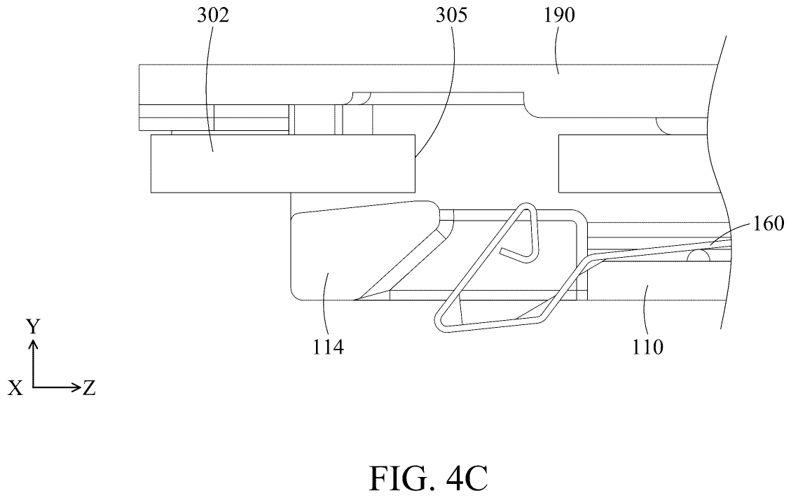

As shown in FIG. 3B, in some embodiments, the holding mechanism 100 includes elastic fasteners 160, connecting members 170 and an operating member 172. The elastic fasteners 160 are disposed on the bottom plate 110 and located between the clamps 120 and the bottom plate 110. When the holding mechanism 100 is engaged with the holding portions 302 of the base 300, the elastic fasteners 160 are located between the holding portions 302 and the bottom plate 110, and in contact with the holding portions 302. The connecting members 170 are rotatably disposed on the bottom plate 110 and located between the knob 140 and the bottom plate 110. One end of the connecting members 170 is in contact with the elastic fastener 160, and the other end is connected to the operating member 172. A part of the operating member 172 is exposed to the accommodation space, and the operating member 172 is located between the knob 140 and the bottom plate 110. In some embodiments, the knob 140 can be rotated to form a gap between the operating member 172 and the knob 140. As a result, a space for the operating member 172 to move can be provided, whereby the users can control the position of the elastic fastener 160 using the operating member 172 so as to facilitate removal of the holding mechanism 100. The operation of the elastic fasteners 160 and the operating member 172 will be further described below with reference to FIGS. 3D and 4C.

It should be noted that FIG. 3A illustrates the locked state in which the holding mechanism 100 is engaged with the base 300. In this state, the bottom plate 110 and the clamps 120 clamp the base 300 to reduce the risk of the holding mechanism 100 being detached from the base 300 during use of the electronic component 200. The connection relationship between the holding mechanism 100 and the base 300 will be described below with reference to FIGS. 3C and 3D.

FIG. 3C illustrates a cross-sectional view of the holding mechanism 100 along the line B-B shown in FIG. 3A in accordance with some embodiments of the present disclosure. As shown in FIG. 3C, the holding mechanism 100 further includes a buffer member 125 that is disposed on the lower surface of the clamp 120, which is the surface of the clamp 120 facing the bottom plate 110. In some embodiments, the buffer member 125 covers the lower surface and a sidewall of the clamp 120 and is in contact with the upper surface of the holding portion 302 of the base 300, which is the surface of the holding portion 302 facing the cover 190. For example, the buffer member 125 may be made of a flexible material (such as rubber or other polymer materials). In this way, the risk of wear between the clamp 120 and the base 300 can be reduced, and the friction between the clamp 120 and the base 300 can be increased. In addition, in some embodiments, the upper surface of the bottom plate 110, which is the surface of the bottom plate 110 facing the cover plate 190, may include a protrusion 111. The protrusion 111 is used to abut against the lower surface of the holding portion 302 of the base 300, which is the surface of the holding portion 302 facing the bottom plate 110. Specifically, the holding portion 302 of the base 300 can be sandwiched between the protrusion 111 of the bottom plate 110 and the buffer member 125 of the clamp 120, thereby reducing the risk of unexpected displacement of the holding portion 302 and detached from the holding mechanism 100.

In some embodiments, the lower surface of the cover plate 190, which is the surface of the cover plate 190 facing the bottom plate 110, includes a protrusion 191, and the protrusion 191 has an inclined surface 192. The clamp 120 includes a groove 128. When the users push the operating portion 142 of the knob 140 so that the cam 145 of the knob 140 pushes the slider 130 to drive the clamps 120 away from each other in the X direction, an inclined surface 192 of the protrusion 191 pushes against one side of the groove 128 of the clamp 120. Accordingly, the clamp 120 moves in the −Y direction toward the holding portion 302 of the base 300 and clamps the holding portion 302. In some embodiments, the clamp 120 contacts and clamps the holding portion 302 via the buffer member 125.

FIG. 3D illustrates a cross-sectional view of the holding mechanism 100 along the line C-C shown in FIG. 3A in accordance with some embodiments of the present disclosure. In some embodiments, when the holding mechanism 100 is installed on the base 300, the base 300 can push against the elastic fastener 160 and press the elastic fastener 160 moves downwardly. In this way, the holding portion 302 of the base 300 can be disposed in the accommodation space between the bottom plate 110 and the cover plate 190 to engage the base 300 with the holding mechanism 100. As shown in FIG. 3D, when the holding portion 302 is in a critical position relative to the holding mechanism 100 (that is, the farthest position that the holding portion 302 can move without detaching from the holding mechanism 100), the elastic fastener 160 is used to extend into the opening 305 of the base 300. In particular, the opening 305 can be disposed on the holding portion 302. When the holding portion 302 is moving away from the accommodation space of the holding mechanism 100 (for example, due to external force), the elastic fastener 160 can extend into the opening 305 of the base 300, so that the elastic fastener 160 abuts against the holding portion 302. Accordingly, the risk of the holding portion 302 detaching from the holding mechanism 100 can be further reduced. In some embodiments, the bottom plate 110 includes a stopper 114 that is used to abut against the elastic fastener 160.

FIG. 4A illustrates a plan view of the holding mechanism 100 in accordance with some embodiments of the present disclosure. It should be noted that FIG. 4A illustrates the unlocked state in which the holding mechanism 100 is to be engaged with the base 300. In this state, the holding mechanism 100 can move freely relative to the base 300 to engage the holding mechanism 100 with the base 300 or to uninstall the holding mechanism 100 from the base 300. As shown in FIG. 4A, the users can operate the operating portion 142 of the knob 140 to rotate the knob 140 around the cam 145 which serves as the central axis. Since the knob 140 abuts against the slider 130, the slider 130 moves along with the knob 140, and the spring 124 drives the clamps 120 to move closer to each other. The connection relationship between the holding mechanism 100 and the base 300 will be described below with reference to FIGS. 4B and 4C.

FIG. 4B illustrates a cross-sectional view of the holding mechanism 100 along the line B-B shown in FIG. 4A in accordance with some embodiments of the present disclosure. As shown in FIG. 4B, when the holding mechanism 100 and the base 300 are in the unlocked state, a sidewall of the groove 128 of the clamp 120 is away from the inclined surface 192 of the protrusion 191, causing the buffer member 125 of the holding mechanism 100 to separate from the holding portion 302 of the base 300 in the Y direction. In this way, the holding mechanism 100 can move freely relative to the base 300. For example, in the unlocked state, the gap between the buffer member 125 and the holding portion 302 may be between about 0.1 mm and about 1 mm, such as about 0.5 mm. As a result, the risk of wear of the holding portion 302, the bottom plate 110 or the clamp 120 during removal or installation of the holding mechanism 100 can be reduced.

FIG. 4C illustrates a cross-sectional view of the holding mechanism 100 along the line C-C shown in FIG. 4A in accordance with some embodiments of the present disclosure. As shown in FIG. 4C, when the users intend to remove the holding mechanism 100 from the base 300, the users can push the knob 140 and pull the operating member 172 in the Y direction, so that the elastic fastener 160 is triggered by the connecting member 170 and leaves the opening 305 the base 300 in the −Y direction. In this way, the holding portion 302 can be detached from the elastic fastener 160 to make it easier to uninstall the holding mechanism 100.

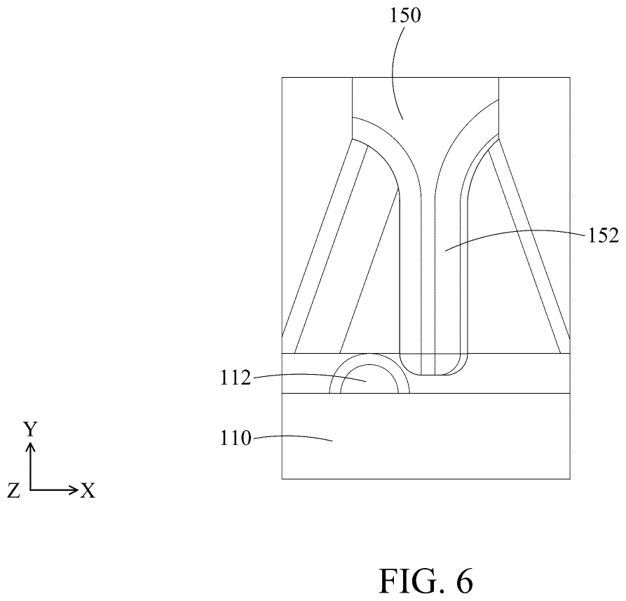

FIG. 5 illustrates a partial plan view of the holding mechanism 100 in accordance with some embodiments of the present disclosure. FIG. 6 illustrates a cross-sectional view of the holding mechanism 100 along the line A-A shown in FIG. 5 in accordance with some embodiments of the present disclosure. As shown in FIG. 5, the clicker 150 can abut against the holding portion 302. In the unlocked state, the user can move the holding mechanism 100 relative to the base 300 in the Z direction. At this time, the holding portion 302 can push the clicker 150 to rotate (while the fixing member 155 serves as the central axis) and make a sound, thereby reminding the users of the distance at which the user base 300 engages with the holding mechanism 100. As shown in FIG. 6, the clicker 150 includes a plurality of protruding portions 152 that extend toward the bottom plate 110 and are used to contact the plurality of protrusions 112 of the bottom plate 110. In other words, the protrusions 112 of the bottom plate 110 are formed within the movement range of the protruding portions 152 of the clicker 150 (or within the coverage range of the clicker 150). Specifically, when the protruding portions 152 of the clicker 150 contact the protrusions 112 of the bottom plate 110, a sound is made. For example, the protruding portions 152 and the protrusions 112 may be arranged along the circumference of the clicker 150.

The numbers of the protruding portions 152 of the clicker 150 and the protrusions 112 of the bottom plate 110 can be adjusted to control the corresponding rotation distance of the clicker 150 when it makes sound. In some embodiments, the number of protruding portions 152 of the clicker 150 is different from the number of protrusions 112 of the bottom plate 110. For example, the clicker 150 may include four protruding portions 152 and the bottom plate 110 may include five protrusions 112. In the case where the protruding portions 152 and the protrusions 112 are both arranged at constant angular intervals, that is, a protrusion 152 is disposed every 90 degrees and a protrusion 112 is disposed every 72 degrees. As a result, every time the clicker 150 rotates 18 degrees (i.e., the angle difference between the protruding portions 152 and the protrusions 112 are arranged), the protruding portions 152 would contact the protrusions 112 to make a sound. Accordingly, the distance between the base 300 and the holding mechanism 100 can be obtained based on the circumference of the clicker 150. It should be understood that the above configuration merely serves as an example, and any possible configuration of the protruding portions 152 and the protrusions 112 is within the scope of the present disclosure.

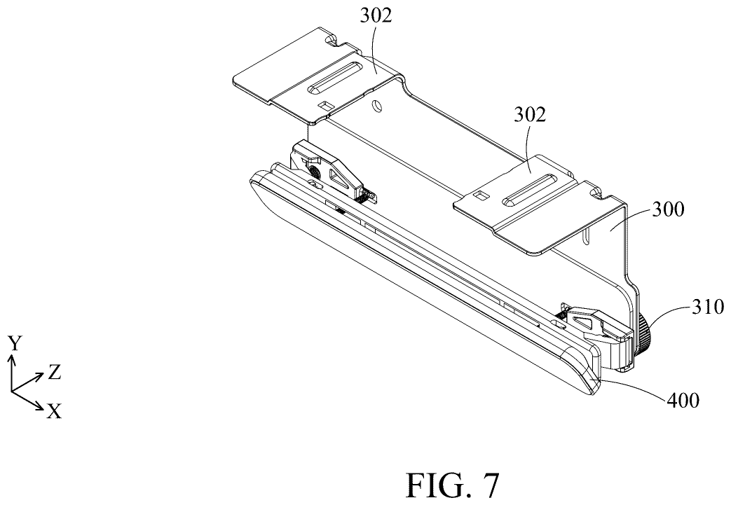

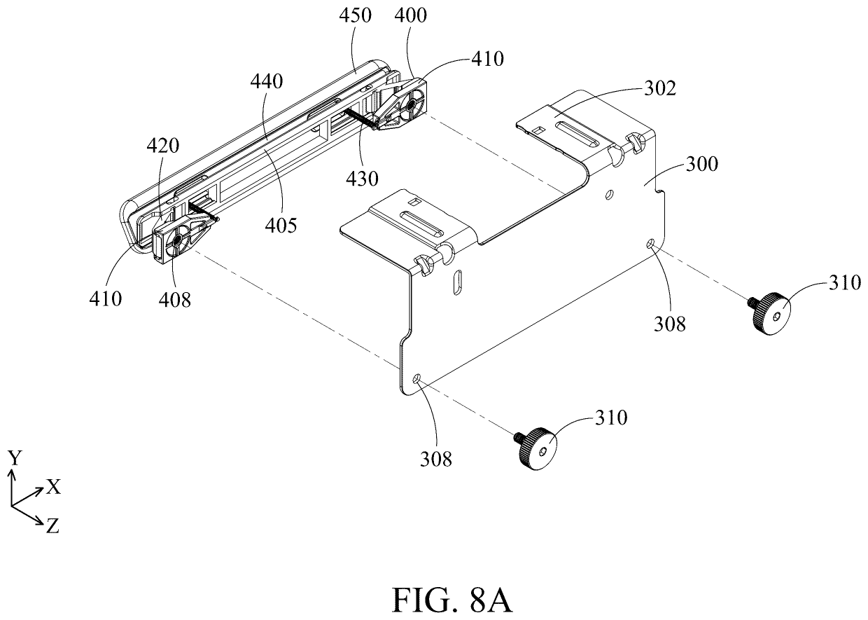

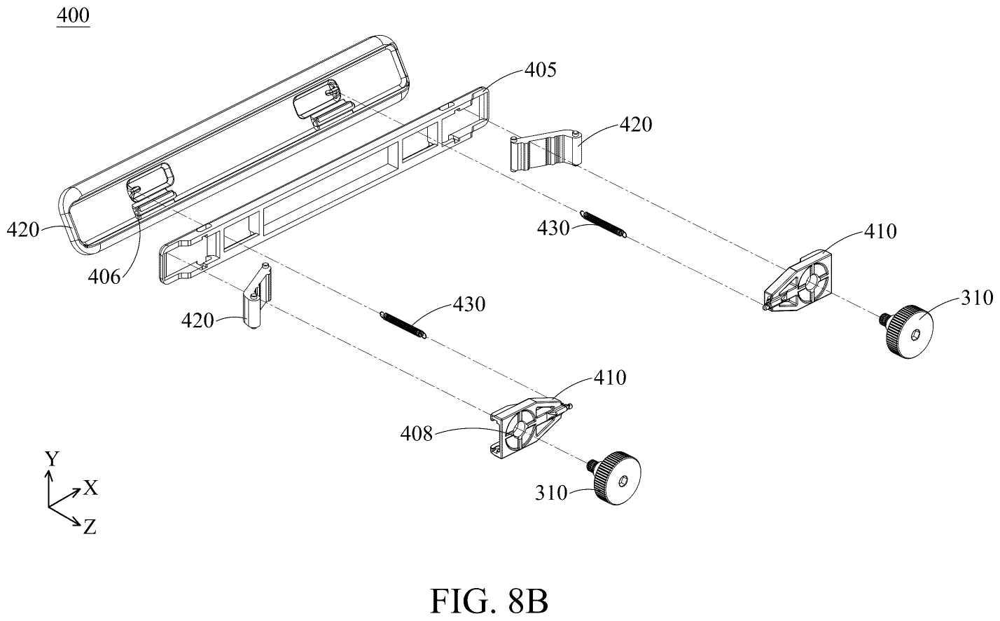

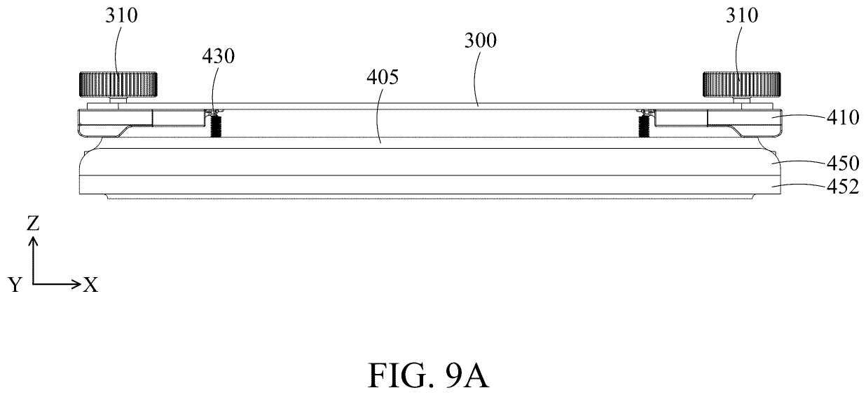

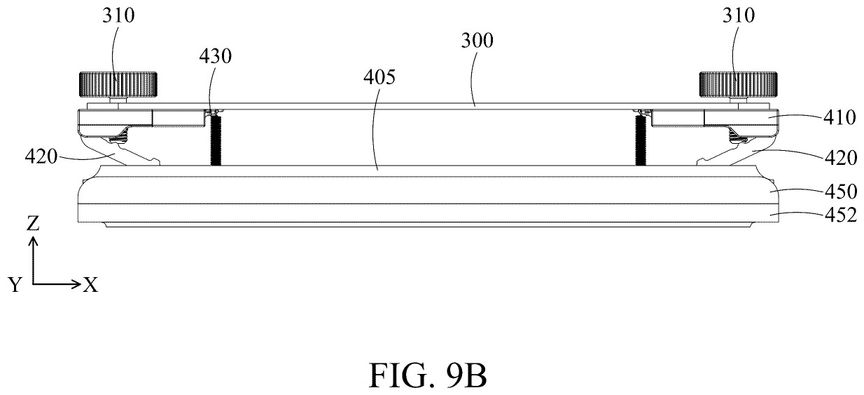

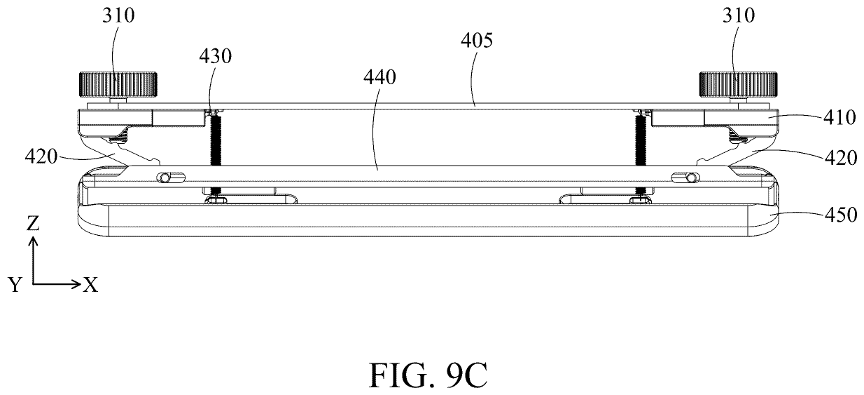

FIG. 7 illustrates a perspective view of the base 300 and the supporting member 400 in accordance with some embodiments of the present disclosure. FIG. 8A illustrates an exploded view of the base 300 and the supporting member 400 in accordance with some embodiments of the present disclosure. FIG. 8B illustrates an exploded view of the supporting member 400 in accordance with some embodiments of the present disclosure. It should be noted that the electronic device 10 may include a supporting member 400 that is used to abut against the surface of the display device 50 (for example, referring to FIG. 1A), so that the electronic device 10 can be disposed on the display device 50. As shown in FIGS. 7, 8A and 8B, the supporting member 400 can be engaged with the base 300 via the locking members 310. To be more specific, the supporting member 400 may include a bracket 405, fixing members 410, a connecting rod 420, elastic elements 430 and a baffle 450. One surface of the baffle 450 is used to abut against the display device 50, and the other surface of the baffle 450 is connected to the fixing members 410 via the elastic elements 430. The bracket 405 is pivotably connected to the baffle 450 via a pivot 406, and the bracket 405 is connected to the fixing members 410 via a connecting rod 420. The supporting member 400 and the base 300 are connected via the locking members 310. Specifically, the locking members 310 can pass through the through holes 308 of the base 300 and the through holes 408 of the fixing members 410 of the supporting member 400, and abut against the connecting rod 420. With such configuration, the users can operate the locking members 310, and the rod bodies (not labeled) of the locking members 310 push the connecting rod 420, so that the bracket 405 connected to the connecting rod 420 can move in a direction away from the fixing members 410. The operation of the supporting member 400 will be further described below with reference to FIGS. 9A through 9C.

FIGS. 9A through 9C illustrate schematic views of various stages of operation of the supporting member 400 in accordance with some embodiments of the present disclosure. As shown in FIG. 9A, the elastic element 430 is connected to the bracket 405 and the baffle 450, and the baffle 450 exerts a pulling force. In some embodiments, a cushion pad 452 may be disposed on the baffle 450 to be engaged with the surface of the display device 50. Then, as shown in FIG. 9B, the users can operate the locking members 310 (for example, rotate it clockwise or counterclockwise), so that the locking members 310 push the connecting rod 420 and then push the baffle 450 away from the fixing member 410. It should be understood that the elastic elements 430 would extend along with the movement of the connecting rod 420. Next, as shown in FIG. 9C, the users can pull the baffle 450 to make the cushion pad 452 fit on the surface of the display device 50. As a result, the supporting member 400 can be stably attached to the non-planar surface of the display device 50, thereby reducing the risk of the electronic device 10 falling off. It should be understood that the users can return the supporting member 400 to its original position based on the reverse process of the above steps, thereby separating the electronic device 10 from the display device 50.

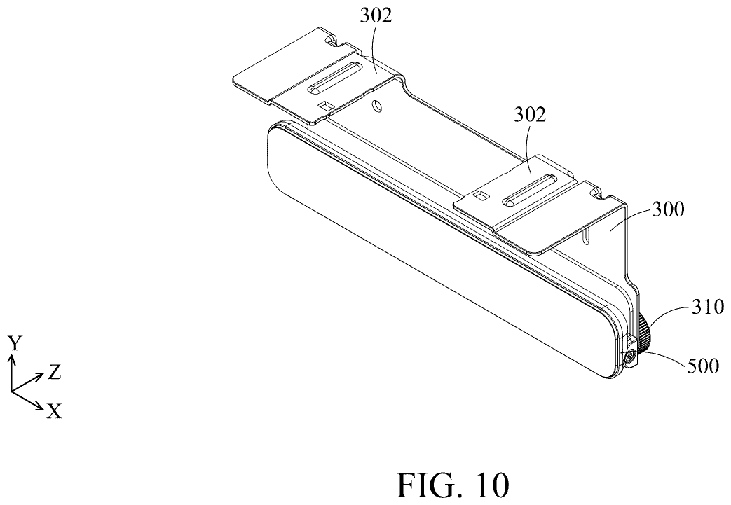

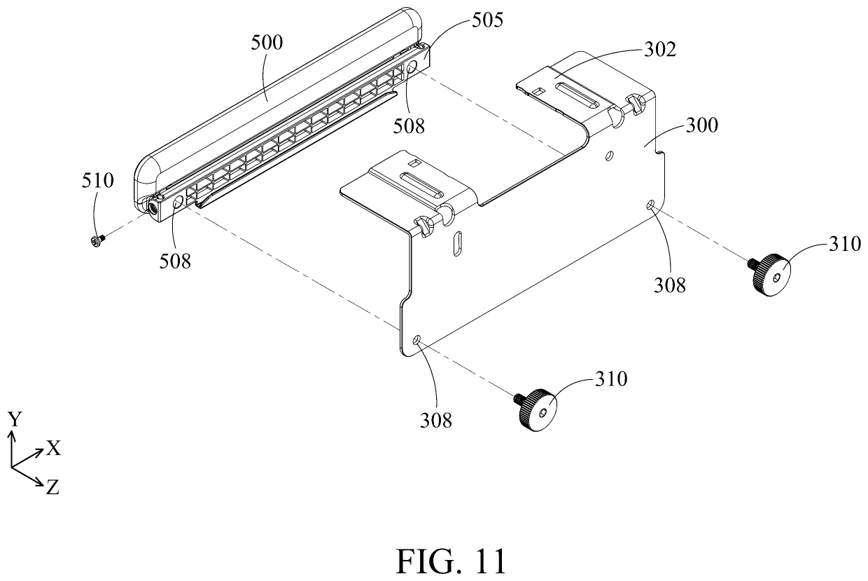

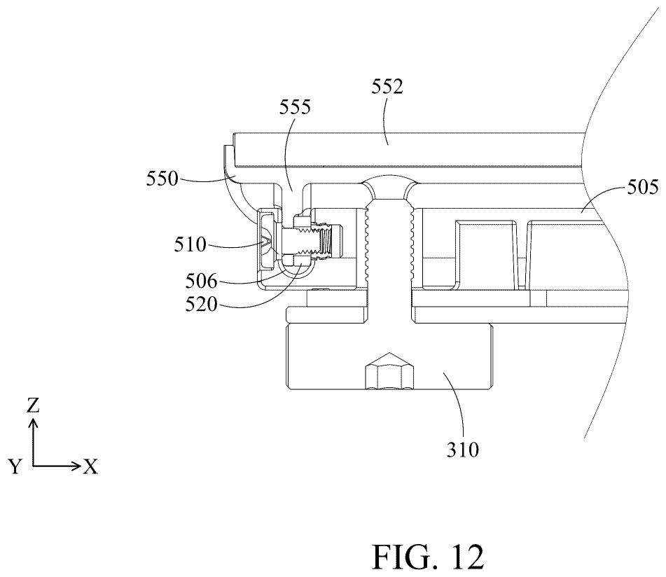

FIG. 10 illustrates a perspective view of the base 300 and the supporting member 500 in accordance with some embodiments of the present disclosure. FIG. 11 illustrates an exploded view of the base 300 and the supporting member 500 in accordance with some embodiments of the present disclosure. It should be noted that the electronic device 10 may include a supporting member 500 that is used to abut against the surface of the display device 50 (for example, referring to FIG. 1A), so that the electronic device 10 can be disposed on the display device 50. As shown in FIGS. 10 and 11, the supporting member 500 may include a fixing member 505 and a torsion member 510 disposed in the fixing member 505. The fixing member 505 of the supporting member 500 can be engaged with the base 300 via the locking members 310. Specifically, the locking members 310 can pass through the through holes 308 of the base 300 and the through holes 508 of the fixing member 505. The operation of the supporting member 500 will be further described below with reference to FIG. 12.

FIG. 12 illustrates a partial cross-sectional view of the base 300 and the supporting member 500 in accordance with some embodiments of the present disclosure. As shown in FIG. 12, the supporting member 500 includes a baffle 550. In some embodiments, a cushion pad 552 may be disposed on the baffle 550 and may be in contact with the surface of the display device 50. In addition, the baffle 550 includes a rotating arm 555 that extends into a groove 506 of the fixing member 505. The torsion member 510 can pass through the rotating arm 555 in the groove 506, whereby the user can pull the baffle 550 to change the direction of the baffle 550, so that the cushion pad 552 fits the surface of the display device 50. In this way, the supporting member 500 can be stably attached to the non-planar surface of the display device 50. Therefore, the risk of the electronic device 10 falling off is reduced. In addition, in some embodiments, a washer 520 may be disposed between the rotating arm 555 and the fixing member 505, and the torsion member 510 passes through the washer 520. With the arrangement of the washer 520, the risk of wear of the rotating arm 555 and the fixing member 505 can be reduced.

As set forth above, the present disclosure provides a holding mechanism and a bracket assembly that include a knob to push the clamps for installation. In this way, the users can easily operate the knob of the holding mechanism to install the holding mechanism on the base. Therefore, the difficulty of installing the holding mechanism and the electronic components held thereon can be reduced. Furthermore, the electronic device may include a rotatable supporting member that is used to abut against a non-planar surface of the display device to facilitate placement of the electronic device on the display device. In addition, the holding mechanism may include a clicker corresponding to the protrusions on the bottom plate, whereby the clicker can make a sound as it rotates to remind the users of the distance that the base engaged with the holding mechanism.

While the embodiments and the advantages of the present disclosure have been described above, it should be understood that those skilled in the art may make various changes, substitutions, and alterations to the present disclosure without departing from the spirit and scope of the present disclosure. In addition, the scope of the present disclosure is not limited to the processes, machines, manufacture, composition, devices, methods and steps in the specific embodiments described in the specification. Those skilled in the art may understand existing or developing processes, machines, manufacture, compositions, devices, methods and steps from some embodiments of the present disclosure. As long as those may perform substantially the same function in the aforementioned embodiments and obtain substantially the same result, they may be used in accordance with some embodiments of the present disclosure. Therefore, the scope of the present disclosure includes the aforementioned processes, machines, manufacture, composition, devices, methods, and steps. Furthermore, each of the appended claims constructs an individual embodiment, and the scope of the present disclosure also includes every combination of the appended claims and embodiments.

What is claimed is:

1. A holding mechanism, comprising:
a bottom plate;
a clamp movably disposed over the bottom plate;
a slider connected to the clamp and used to drive the clamp to move; and
a knob rotatably disposed over the bottom plate, wherein the knob abuts the slider,
wherein the slider is pushed to move the clamp towards the base by the knob.

2. The holding mechanism as claimed in claim 1, further comprising a spring connected to the clamp and used to exert a force on the clamp so that the clamp moves toward a cover plate.

3. The holding mechanism as claimed in claim 1, further comprising a buffer member disposed over a surface of the clamp, wherein the surface of the clamp faces the bottom plate.

4. The holding mechanism as claimed in claim 1, further comprising a cover plate, wherein the cover plate is disposed opposite the bottom plate, the cover plate comprises a protrusion, the clamp comprises a groove, and the protrusion of the cover plate is used to push against a sidewall of the groove of the clamp, so that the clamp is moved toward the bottom plate.

5. The holding mechanism as claimed in claim 1, further comprising a cam, wherein the knob is pivotally connected to the bottom plate via the cam.

6. The holding mechanism as claimed in claim 1, further comprising an operating portion extending from the knob and in a direction away from the bottom plate.

7. A bracket assembly, for carrying an electronic component, comprising:
a base; and
a holding mechanism, movably connected to the base and used to carry the electronic component, wherein the holding mechanism comprises:
a bottom plate;
a cover plate, wherein the cover plate is disposed opposite the bottom plate;
a clamp movably disposed over the bottom plate;
a slider connected to the clamp and used to drive the clamp to move; and
a knob rotatably disposed on the bottom plate and abutting against the slider,
wherein the base is slidably disposed between the bottom plate of the holding mechanism and the clamp, and the slider is pushed to move the clamp toward the base by the knob, so that the bottom plate and the clamp contact opposite surfaces of the base respectively.

8. The bracket assembly as claimed in claim 7, wherein the holding mechanism further includes an elastic fastener and a connecting member, the elastic fastener is disposed on the bottom plate and is in contact with the base, and the connecting member is rotatably disposed on the bottom plate and is in contact with the elastic fastener, wherein the elastic fastener is pushed by the connecting member and extends into an through hole of the base.

9. The bracket assembly as claimed in claim 8, wherein the holding mechanism further comprises an operating member connected to the connecting member, and the connecting member is driven to push against the elastic fastener by the operating member.

10. The bracket assembly as claimed in claim 7, wherein the holding mechanism further comprises a buffer member disposed on a surface of the clamp facing the bottom plate, and the clamp is used to contact the buffer member and a surface of the base.

11. The bracket assembly as claimed in claim 7, wherein the bottom plate comprises a protrusion, and the protrusion abuts against a surface of the base.

12. The bracket assembly as claimed in claim 7, wherein the cover plate comprises a protrusion, and the clamp comprises a groove, and the protrusion of the cover plate is used to push against a sidewall of the clamp so as to move the clamp toward the base.

13. The bracket assembly as claimed in claim 7, wherein the holding mechanism further comprises a joint member, and the joint member is disposed on the cover plate and is used to engage the electronic component.

14. The bracket assembly as claimed in claim 7, further comprising a clicker, rotatably disposed on the bottom plate, wherein the clicker abuts against the base.

15. A bracket assembly, for abutting against a display device, comprising:
a base; and
a holding mechanism movably connected to the base and used to abut against the display device, wherein the holding mechanism comprises:
a bottom plate;
a clamp movably disposed over the bottom plate;
a slider connected to the clamp and used to drive the clamp to move; and
a knob rotatably disposed over the bottom plate, wherein the knob is abutted against the slider,
wherein the base is slidably disposed between the bottom plate and the clamp of the holding mechanism, and the slider is pushed to move the clamp toward the base through the knob, so that the bottom plate and the clamp contact opposite surfaces of the base respectively.

16. The bracket assembly as claimed in claim 15, further comprising a supporting member and a locking member, and the supporting member is connected to the base via the locking member, wherein the supporting member and the holding mechanism are used to abut against different sides of the display device.

17. The bracket assembly as claimed in claim 16, wherein the supporting member comprises a baffle and a fixing member, the baffle is rotatably connected to the fixing member, and the fixing member of the supporting member is connected to the base via the locking member.

18. The bracket assembly as claimed in claim 17, wherein the supporting member comprises a bracket and a connecting rod, the baffle is pivotally connected to the bracket, the bracket is connected to the fixing member via the connecting rod, and the locking member passes through the fixing member and is used to push the connecting rod so that the bracket moves away from the fixing member.

19. The bracket assembly as claimed in claim 18, wherein the supporting member comprises an elastic element connected between the baffle and the fixing member, and the elastic element is used to exert a force on the baffle so that the baffle moves toward the fixing member.

20. The bracket assembly as claimed in claim 17, wherein the supporting member comprises a torsion member passing through the baffle and connected to the fixing member.
